(19) United States
(12) Patent Application Publication
(10) Pub. No.: US 2016/0111136 A1
(43) Pub. Date: Apr. 21, 2016

(54) ADDRESS DECODING CIRCUIT AND SEMICONDUCTOR APPARATUS INCLUDING THE SAME

(71) Applicant: SK hynix Inc., Icheon-si Gyeonggi-do (KR)

(72) Inventor: Kyeong Min CHAE, Icheon-si Gyeonggi-do (KR)

(21) Appl. No.: 14/586,362

(22) Filed: Dec. 30, 2014

(30) Foreign Application Priority Data
Oct. 16, 2014 (KR) 10-2014-0139841

(51) Int. Cl. G11C 8/10; G11C 8/18; G11C 8/06

(52) U.S. Cl. CPC G11C 8/10; G11C 8/06; G11C 8/18

(57) ABSTRACT

An address decoding circuit may include a main address processing block configured to latch a main address, and output a latched main address. The address decoding circuit may include a repair block configured to determine whether the main address corresponds to a failed region, and output a repair address and a repair signal according to a determination result. The address decoding circuit may include a synchronization block configured to synchronize the latched main address, the repair address and the repair signal with a synchronization signal, and output a synchronized main address, a synchronized repair address and a synchronized repair signal. The address decoding circuit may include a decoder configured to decode any one of the synchronized main address and the synchronized repair address in response to a decoding signal.

### CROSS-REFERENCES TO RELATED APPLICATION

The present application claims priority under 35 U.S.C. §119(a) to Korean application number 10-2014-0139841, filed on Oct. 16, 2014, in the Korean Intellectual Property Office, which is incorporated herein by reference in its entirety.

### BACKGROUND

1. Technical Field

Various embodiments generally relate to a semiconductor apparatus, and more particularly, to a circuit for decoding the address inputted to a semiconductor memory apparatus.

2. Related Art

Semiconductor apparatuses, specifically, semiconductor memory apparatuses may be used to store data. Memory apparatuses may be generally divided into two types of apparatuses. One type may be nonvolatile and the other type may be volatile.

A nonvolatile memory apparatus may retain stored data even though power is not applied. The nonvolatile memory apparatus may include a flash memory apparatus. For example, a flash memory apparatus such as a NAND flash and a NOR flash, an FeRAM (ferroelectric random access memory), a PCRAM (phase change random access memory), an MRAM (magnetic random access memory) or an ReRAM (resistive random access memory).

A volatile memory apparatus may not retain stored data when power is not applied. In this manner the volatile memory apparatus may lose stored data when power is not applied. The volatile memory apparatus may include, for example, an SRAM (static random access memory) or a DRAM (dynamic random access memory). The volatile memory apparatus may be generally used as a buffer memory apparatus, a cache memory apparatus, a working memory apparatus, or the like, in a data processing system, based on a relatively high processing speed.

### SUMMARY

In an embodiment, an address decoding circuit may include a main address processing block configured to latch a main address, and output a latched main address. The address decoding circuit may include a repair block configured to determine whether the main address corresponds to a failed region, and output a repair address and a repair signal according to a determination result. The address decoding circuit may include a synchronization block configured to synchronize the latched main address, the repair address and the repair signal with a synchronization signal, and output a synchronized main address, a synchronized repair address and a synchronized repair signal. The address decoding circuit may include a decoder configured to decode any one of the synchronized main address and the synchronized repair address in response to a decoding signal.

In an embodiment, an address decoding circuit may include a main address processing block configured to delay a main address, and output a delayed main address as a second main address. The address decoding circuit may include a repair block configured to determine whether the main address corresponds to a failed region, and output a repair address according to a determination result. The address decoding circuit may include a synchronization block configured to synchronize the second main address and the repair address with a synchronization signal, and output a synchronized second main address and a synchronized repair address. The address decoding circuit may include a decoder configured to decode any one of the synchronized second main address and the synchronized repair address.

In an embodiment, a semiconductor apparatus may include a memory region including a main region and a redundancy region. The semiconductor apparatus may include an address decoding circuit configured to process a main address corresponding to the main region, the address decoding circuit including a main address processing block configured to latch the main address, and output a latched main address. The semiconductor apparatus may include a repair block configured to output a repair address and a repair signal, by referring to the main address and information on a failed region. The semiconductor apparatus may include a synchronization block configured to synchronize the latched main address, the repair address and the repair signal with a synchronization signal, and output a synchronized main address, a synchronized repair address and a synchronized repair signal. The semiconductor apparatus may include a decoder configured to decode any one of the synchronized main address and the synchronized repair address in response to a decoding signal.

### BRIEF DESCRIPTION OF THE DRAWINGS

FIG. 1 is a block diagram schematically illustrating an example of a representation of an address decoding circuit in accordance with an embodiment.

FIG. 2 is a block diagram schematically illustrating an example of a representation of the main address processing block illustrated in FIG. 1.

FIG. 3 is a circuit diagram illustrating an example of a representation of the first sub processing unit illustrated in FIG. 2.

FIG. 4 is an example of a representation of a waveform diagram to assist in the explanation of an operating method of the address decoding circuit illustrated in FIG. 1.

FIG. 5 is an example of a representation of a diagram to assist in the explanation of the effects achieved by the address decoding circuit of FIG. 1.

FIG. 6 is a block diagram schematically illustrating an example of a representation of a semiconductor apparatus in accordance with an embodiment.

FIG. 7 illustrates a block diagram of an example of a representation of a system including the semiconductor apparatus and/or address decoding circuit in accordance with the embodiments discussed above with relation to FIGS. 1-6.

### DETAILED DESCRIPTION

Hereinafter, an address decoding circuit and a semiconductor apparatus including the same will be described below with reference to the accompanying drawings through various examples of embodiments.

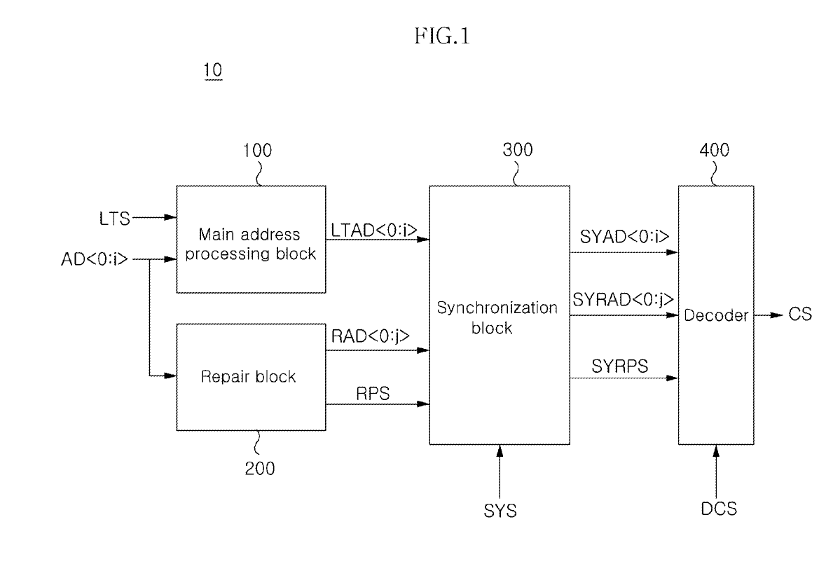

FIG. 1 is a block diagram schematically illustrating an example of a representation of an address decoding circuit 10 in accordance with an embodiment.

The address decoding circuit 10 may output a control signal CS. The control signal CS may be outputted for accessing a specific region of the memory region (not shown) of a semiconductor apparatus, according to a main address AD<0:i> inputted into the address decoding circuit 10. For example, the address decoding circuit 10 may output the control signal CS by decoding the main address AD<0:i>, in the examples where the inputted main address AD<0:i> corresponds to a normal region of the memory region. Accordingly, the normal region corresponding to the main address AD<0:i> may be accessed. In an embodiment, the address decoding circuit 10 may output the control signal CS by decoding a repair address RAD<0:j> instead of the main address AD<0:i>, in the examples where the inputted main address AD<0:i> corresponds to a failed region of the memory region. Accordingly, a redundancy region corresponding to the repair address RAD<0:j> may be accessed instead of the corresponding failed region.

The address decoding circuit 10 may include, for example, a main address processing block 100, a repair block 200, a synchronization block 300, and a decoder 400.

The main address processing block 100 may receive the main address AD<0:i>. The main address processing block 100 may latch the inputted main address AD<0:i> in response to a latch signal LTS, and output a latched main address LTAD<0:i>. The main address processing block 100 may delay and output the inputted main address AD<0:i>.

The repair block 200 may receive the main address AD<0:i>. The repair block 200 may determine whether the inputted main address AD<0:i> corresponds to a failed region, and output the repair address RAD<0:j> and a repair signal RPS according to a determination result. The repair block 200 may determine whether the main address AD<0:i> corresponds to a failed region. For example, the repair block 200 may determine whether the main address AD<0:i> corresponds to a failed region by comparing the main address AD<0:i> with the address of a failed region. The repair block 200 may determine that the main address AD<0:i> corresponds to a failed region, in the examples where the main address AD<0:i> is the same as the address of a failed region. In the examples where it is determined that the main address AD<0:i> corresponds to a failed region, the repair block 200 may output the repair address RAD<0:j> of a redundancy region for replacing the failed region and the repair signal RPS which is enabled (i.e., at a predetermined level). In the examples where it is determined that the main address AD<0:i> does not correspond to a failed region, the repair block 200 may output the repair signal RPS which is disabled (i.e., at a predetermined level).

The repair block 200 may store information on the addresses of failed regions to be compared with the main address AD<0:i>, that is, failed region information. The repair block 200 may store information on the addresses of redundancy regions to be outputted as the repair address RAD<0:j>according to a determination result with respect to the main address AD<0:i>.

The synchronization block 300 may receive the latched main address LTAD<0:i>, the repair address RAD<0:j> and the repair signal RPS and synchronize them with a synchronization signal SYS. The synchronization block 300 may output a synchronized main address SYAD<0:i>, a synchronized repair address SYRAD<0:j> and a synchronized repair signal SYRPS, to the decoder 400. The synchronization block 300 may include a plurality of flip-flops. The plurality of flip-flops may output inputted signals in response to the synchronization signal SYS.

The decoder 400 may decode any one of the synchronized main address SYAD<0:i> and the synchronized repair address SYRAD<0:j> in response to a decoding signal DCS. The decoder 400 may decode any one of the synchronized main address SYAD<0:i> and the synchronized repair address SYRAD<0:j> according to the synchronized repair signal SYRPS. The decoder 400 may decode the synchronized main address SYAD<0:i> in the examples where the synchronized repair signal SYRPS is disabled (i.e., at a predetermined level). The decoder 400 may decode the synchronized repair address SYRAD<0:j> in the examples where the synchronized repair signal SYRPS is enabled (i.e., at a predetermined level). The decoder 400 may output the control signal CS as a decoding result.

According to an embodiment, the main address processing block 100 may compensate for the processing time of the repair block 200 by latching the main address AD<0:i>, such that the synchronization block 300 may sufficiently secure a timing margin for synchronizing the latched main address LTAD<0:i> and the repair address RAD<0:j>. A time for the main address processing block 100 to latch the main address AD<0:i> may be controlled based on the processing time of the repair block 200. Also, the time for the main address processing block 100 to latch the main address AD<0:i> may be controlled in consideration of the timing margin of the synchronization block 300. For example, the main address processing block 100 may latch the main address AD<0:i> while the repair block 200 outputs the repair address RAD<0:j>. In this way, the signal transmission of a semiconductor apparatus may be implemented at high speeds.

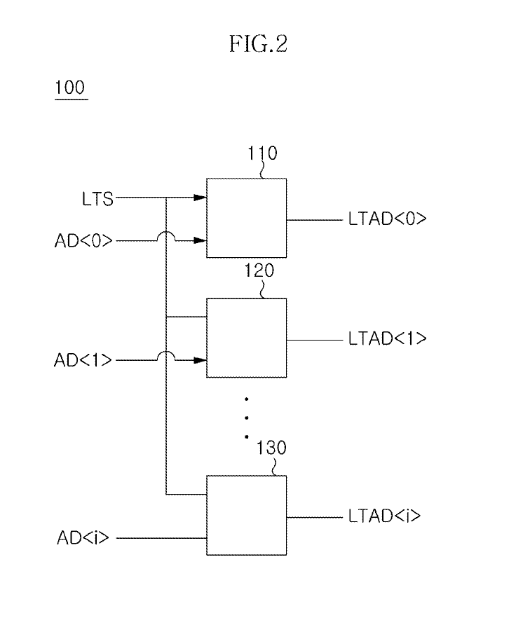

FIG. 2 is a block diagram schematically illustrating an example of a representation of the main address processing block 100 illustrated in FIG. 1.

The main address processing block 100 may include a plurality of sub processing units 110 to 130.

When the main address AD<0:i> is configured by a plurality of bits, the plurality of respective sub processing units 110 to 130 may receive the corresponding bits of the main address AD<0:i>. The plurality of respective sub processing units 110 to 130 may latch the corresponding bits of the inputted main address AD<0:i>. The corresponding bits of the inputted main address AD<0:i> may be latched in response to the latch signal LTS, and the plurality of respective sub processing units 110 to 130 may output the corresponding bits of the latched main address LTAD<0:i>. The plurality of respective sub processing units 110 to 130 may delay and output the corresponding bits of the inputted main address AD<0:i>.

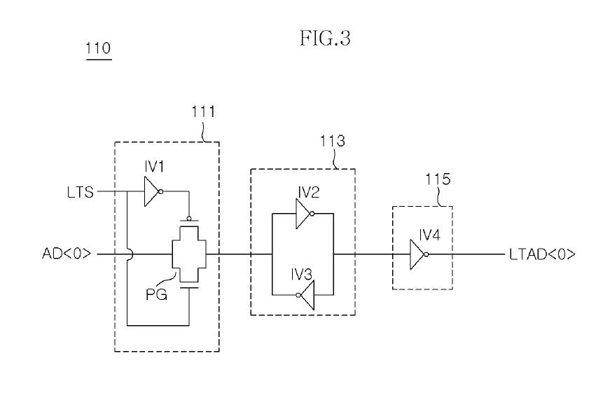

FIG. 3 is a circuit diagram illustrating an example of a representation of the sub processing unit 110 (i.e., first sub processing unit 110) illustrated in FIG. 2. Since the plurality of sub processing units 110 to 130 of FIG. 2 may be configured and operate in substantially the same way, the first sub processing unit 110 will be described below as an example, for the sake of convenience in explanation.

The first sub processing unit 110 may latch the corresponding bit AD<0> of the main address AD<0:i> in response to the latch signal LTS, and output the corresponding bit LTAD<0> of the latched main address LTAD<0:i>. The first sub processing unit 110 may delay and output the corresponding bit AD<0> of the main address AD<0:i>.

The first sub processing unit 110 may include a transfer section 111, a latch section 113, and an output section 115.

The transfer section 111 may receive the corresponding bit AD<0> of the main address AD<0:i>, and output the corresponding inputted bit AD<0> to the latch section 113 in response to the latch signal LTS. The transfer section 111 may output the corresponding bit AD<0> to the latch section 113 in the examples where the latch signal LTS is enabled (i.e., at a predetermined level), and may intercept the corresponding bit AD<0> in the examples where the latch signal LTS is disabled (i.e., at a predetermined level).

The transfer section 111 may include, for example, a first inverter IV1 and a pass gate PG. The first inverter IV1 may invert the latch signal LTS and output a resultant signal. The pass gate PG may transfer the corresponding bit AD<0> to the latch section 113 in response to the latch signal LTS and the output signal of the first inverter IV1.

The latch section 113 may latch the corresponding bit

AD<0> transferred from the transfer section 111. The latch section 113 may include a second inverter IV2 and a third inverter IV3. The second inverter IV2 may invert the corresponding bit AD<0> transferred from the transfer section 111, and output a resultant signal. The third inverter IV3 may invert the output of the second inverter IV2, and output a resultant signal to the second inverter IV2.

The output section 115 may output the corresponding bit LTAD<0> (of the latched main address LTAD<0:i>) latched by the latch section 113. The output section 115 may include a fourth inverter IV4. The fourth inverter IV4 may invert the output of the second inverter IV2, and output a resultant signal. The resultant signal may include the corresponding bit LTAD<0> of the latched main address LTAD<0:i>.

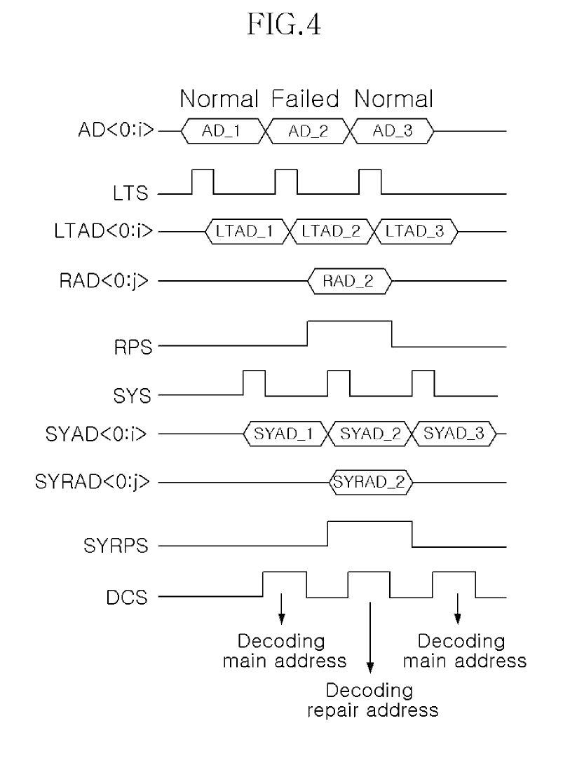

FIG. 4 is an example of a representation of a waveform diagram to assist in the explanation of an operating method of the address decoding circuit 10 illustrated in FIG. 1. In FIG. 4, it is assumed for example that, among the main addresses AD<0:i> inputted to the address decoding circuit 10, a main address AD_1 corresponds to a normal region, a main address AD_2 corresponds to a failed region, and a main address AD_3 corresponds to a normal region.

Hereinbelow, an operating method of the address decoding circuit 10 will be described with reference to FIGS. 1 and 4.

The address decoding circuit 10 may receive the main address AD_1. The main address AD_1 may be inputted to the main address processing block 100 and the repair block 200.

The main address processing block 100 may latch the main address AD_1 in response to the latch signal LTS, and output a latched main address LTAD_1.

The repair block 200 may determine whether the inputted main address AD_1 corresponds to a failed region, and output the repair address RAD<0:j> and the repair signal RPS according to a determination result. According to the assumption, the repair block 200 determines that the main address AD_1 does not correspond to a failed region. Accordingly, the repair block 200 may output the repair signal RPS which is disabled (i.e., at a predetermined level). The repair address RAD<0:j> outputted at this time may be a meaningless signal.

The synchronization block 300 may synchronize the latched main address LTAD_1, the repair address RAD<0:j> and the repair signal RPS with the synchronization signal SYS, and output a synchronized main address SYAD_1, the synchronized repair address SYRAD<0:j> and the synchronized repair signal SYRPS.

The decoder 400 may decode any one of the synchronized main address SYAD_1 and the synchronized repair address SYRAD<0:j> in response to the decoding signal DCS. Since the synchronized repair signal SYRPS is in the disabled state (i.e., at a predetermined level), the decoder 400 may decode the synchronized main address SYAD_1, and output a decoding result as the control signal CS.

Next, the address decoding circuit 10 may receive the main address AD_2. The main address AD_2 may be inputted to the main address processing block 100 and the repair block 200.

The main address processing block 100 may latch the main address AD_2 in response to the latch signal LTS, and output a latched main address LTAD_2.

The repair block 200 may determine whether the inputted main address AD_2 corresponds to a failed region. The repair block 200 may output the repair address RAD<0:j> and the repair signal RPS according to a determination result. According to the assumption, the repair block 200 determines that the main address AD_2 corresponds to a failed region. Accordingly, the repair block 200 may output a repair address RAD_2 of a redundancy region for replacing the failed region, and the repair signal RPS which is enabled (i.e., at a predetermined level).

The synchronization block 300 may synchronize the latched main address LTAD_2, the repair address RAD_2 and the repair signal RPS with the synchronization signal SYS, and output a synchronized main address SYAD_2, a synchronized repair address SYRAD_2 and the synchronized repair signal SYRPS.

The decoder 400 may decode any one of the synchronized main address SYAD_2 and the synchronized repair address SYRAD_2. The decoder 400 may decode any one of the synchronized main address SYAD_2 and the synchronized repair address SYRAD_2 in response to the decoding signal DCS. Since the synchronized repair signal SYRPS is in the enabled state (i.e., at a predetermined level), the decoder 400 may decode the synchronized repair address SYRAD_2, and output a decoding result as the control signal CS.

Then, the address decoding circuit 10 may receive the main address AD_3 corresponding to a normal region. The address decoding circuit 10 may operate in substantially the same way as in the operating method having previously processed the main address AD_1.

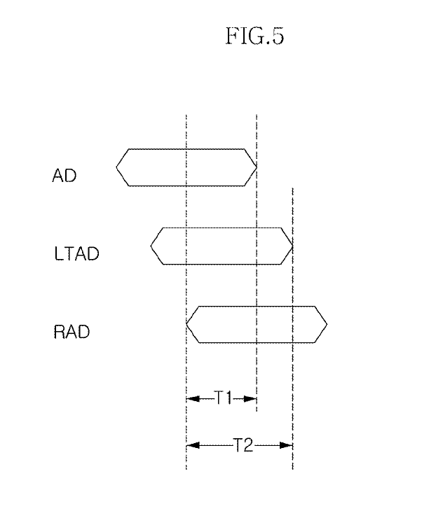

FIG. 5 is an example of a representation of a diagram to assist in the explanation of the effects achieved by the address decoding circuit 10 of FIG. 1.

In order to allow the decoder 400 to selectively decode any one of the main addresses AD<0:i> and the repair addresses RAD<0:j> in response to the decoding signal DCS enabled (i.e., at a predetermined level) with a predetermined frequency, the synchronization block 300 should provide the synchronized main address SYAD<0:i>, the synchronized repair address SYRAD<0:j> and the synchronized repair signal SYRPS to the decoder 400. Although the operation margin of the synchronization block 300 may give rise to an unwanted issue because the repair address RAD<0:j> is outputted through the determination process of the repair block 200 with respect to the main address AD<0:i>, however according to an embodiment, the operation margin of the synchronization block 300 may be sufficiently secured through the main address processing block 100.

Referring to FIG. 5, the main address processing block 100 may latch the main address AD, and output the latched main address LTAD to the synchronization block 300. The repair block 200 may determine whether the main address AD corresponds to a failed region, and output the repair address RAD to the synchronization block 300. As a result, the synchronization block 300 may secure a timing margin for synchronizing the latched main address LTAD and the repair address RAD with the synchronization signal SYS, by a second time T2.

If the main address AD is directly inputted to the synchronization block 300 without passing through the main address processing block 100, the synchronization block 300 may secure a timing margin for synchronizing the main address AD and the repair address RAD with the synchronization signal SYS, by only a first time T1.

In summary, the main address processing block 100 may compensate for the processing time of the repair block 200 by latching the main address AD<0:i>, such that the synchronization block 300 may sufficiently secure a timing margin for synchronizing the latched main address LTAD<0:i>and the repair address RAD<0:j>. A time for the main address processing block 100 to latch the main address AD<0:i> may be controlled based on the processing time of the repair block 200. The time for the main address processing block 100 to latch the main address AD<0:i> may be controlled in consideration of the timing margin of the synchronization block 300. For example, the main address processing block 100 may latch the main address AD<0:i> while the repair block 200 outputs the repair address RAD<0:j>. In these examples, the synchronization block 300 may maximally secure a timing margin for synchronizing the latched main address LTAD<0:i> and the repair address RAD<0:j>.

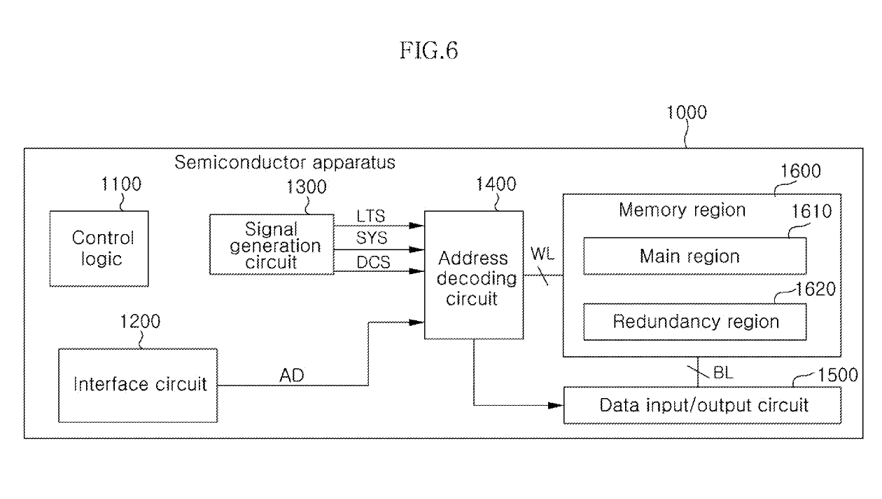

FIG. 6 is a block diagram schematically illustrating an example of a representation of a semiconductor apparatus 1000 in accordance with an embodiment. The semiconductor apparatus 1000 may be, for example, but not limited to, a nonvolatile memory apparatus.

The semiconductor apparatus 1000 may operate according to the control of an external device (not shown) such as a host device and a controller. For example, the semiconductor apparatus 1000 may store data in response to a write command provided from an external device, and transmit stored data to the external device in response to a read command.

The semiconductor apparatus 1000 may include a control logic 1100, an interface circuit 1200, and a signal generation circuit 1300. The semiconductor apparatus 1000 may include an address decoding circuit 1400, a data input/output circuit 1500, and a memory region 1600.

The control logic 1100 may control the general operations of the semiconductor apparatus 1000. The control logic 1100 may control a write, read or erase operation for the memory region 1600, in response to an access command provided from the external device, for example, a write, read or erase command.

The interface circuit 1200 may exchange various control signals including access commands and data, with the external device. The interface circuit 1200 may transmit various control signals and data which are inputted thereto, to the internal units of the semiconductor apparatus 1000. The interface circuit 1200 may transmit a main address AD inputted from the external device, to the address decoding circuit 1400.

The signal generation circuit 1300 may generate a latch signal LTS, a synchronization signal SYS and a decoding signal DCS and provide them to the address decoding circuit 1400, according to the control of the control logic 1100.

The address decoding circuit 1400 may control word lines WL to be selectively driven according to the main address AD corresponding to a main region 1610. The address decoding circuit 1400 may control the data input/output circuit 1500 such that bit lines BL are selectively driven according to the main address AD. The address decoding circuit 1400 may determine whether the main region 1610 corresponding to the main address AD is a failed region, by referring to information on main addresses AD and failed regions, and may decode the main address AD or a repair address corresponding to a redundancy region 1620, according to a determination result. The address decoding circuit 1400 may be configured and operate substantially similarly to the address decoding circuit 10 illustrated in FIG. 1.

The data input/output circuit 1500 may transmit the data transmitted from the interface circuit 1200, to the memory region 1600 through the bit lines BL. The data input/output circuit 1500 may transmit the data read from the memory region 1600 through the bit lines BL, to the interface circuit 1200.

The memory region 1600 may include a plurality of memory cells (not shown) which are respectively disposed at regions where the word lines WL and the bit line BL cross each other. The memory cells may be classified according to the number of bits which are stored in each cell. For example, the memory cells may be classified into single level cells each of which stores 1 bit and multi-level cells each of which stores at least 2 bits.

The memory region 1600 may include the main region 1610 and the redundancy region 1620 which may replace the main region 1610 in the examples where the main region 1610 has a fail. The memory region 1600 may store information on failed regions, and the information on failed regions may be loaded on the address decoding circuit 1400, for example, when starting an operation, and may be used for the address decoding circuit 1400 to perform comparison and determination with respect to the main address AD.

As is apparent from the above descriptions, the address decoding circuit in accordance with the embodiments may improve a timing margin for synchronizing a main address and a repair address.

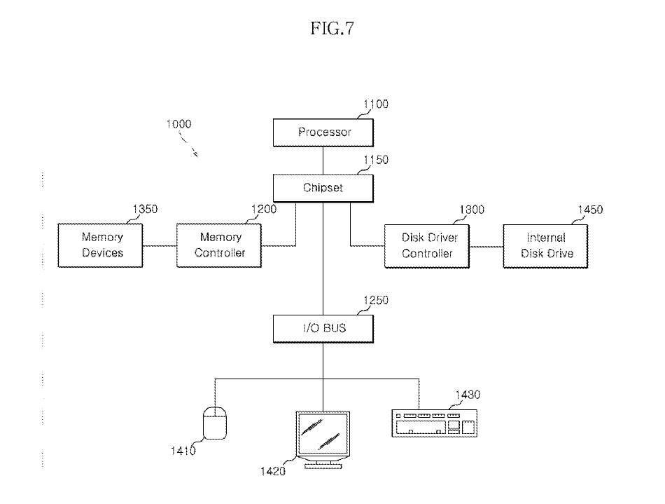

The semiconductor apparatuses and/or address decoding circuits discussed above (see FIGS. 1-6) are particular useful in the design of memory devices, processors, and computer systems. For example, referring to FIG. 7, a block diagram of a system employing the semiconductor apparatus and/or address decoding circuit in accordance with the embodiments are illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150. The memory controller 1200 may include at least one semiconductor apparatus and/or address decoding circuit as discussed above with reference to FIGS. 1-6. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor apparatus and/or address decoding circuit as discussed above with relation to FIGS. 1-6, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 (i.e., internal disk drive) may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 7 is merely one example of a system including the semiconductor apparatuses and/or address decoding circuits as discussed above with relation to FIGS. 1-6. In alternate embodiments, such as cellular phones or digital cameras, the components may differ from the embodiments illustrated in FIG. 7.

While various embodiments have been described above, it will be understood to those skilled in the art that the embodiments described are by way of example only. Accordingly, the address decoding circuit and the semiconductor apparatus including the same described herein should not be limited based on the described embodiments.

What is claimed is:

1. An address decoding circuit comprising:
a main address processing block configured to latch a main address, and output a latched main address;
a repair block configured to determine whether the main address corresponds to a failed region, and output a repair address and a repair signal according to a determination result;
a synchronization block configured to synchronize the latched main address, the repair address and the repair signal with a synchronization signal, and output a synchronized main address, a synchronized repair address and a synchronized repair signal; and
a decoder configured to decode any one of the synchronized main address and the synchronized repair address in response to a decoding signal.

2. The address decoding circuit according to claim 1, wherein the main address processing block is configured to latch the main address in response to a latch signal.

3. The address decoding circuit according to claim 1, wherein the main address processing block latches the main address while the repair block outputs the repair address and the repair signal.

4. The address decoding circuit according to claim 2, wherein the main address processing block comprises:
a plurality of sub-processing units configured to receive corresponding bits of the main address, latch the corresponding bits of the main address in response to the latch signal, and output corresponding bits of the latched main address.

5. The address decoding circuit according to claim 4, wherein each of the sub-processing units comprise:
a transfer section configured to receive the main address, and output the main address in response to the latch signal;
a latch section configured to latch the main address transferred from the transfer section; and
an output section configured to output the main address latched by the latch section.

6. The address decoding circuit according to claim 2,
wherein the transfer section includes a first inverter configured to receive the latch signal and output a resultant signal to a pass gate, the pass gate configured to receive the corresponding bit of the main address and the resultant signal and output the corresponding bit to the latch section,
wherein the latch section includes a second inverter configured to receive the corresponding bit from the transfer section and output a resultant signal to a third inverter and to the output section, and
wherein the output section includes a fourth inverter configured to receive the resultant signal from the second inverter, invert the resultant signal from the second inverter, and output the corresponding bit of the latched main address.

7. The address decoding circuit according to claim 2, wherein the main address processing block comprises:
a transfer section configured to receive the main address, and output the main address in response to the latch signal;
a latch section configured to latch the main address transferred from the transfer section; and
an output section configured to output the main address latched by the latch section.

8. The address decoding circuit according to claim 1, wherein the decoder decodes any one of the synchronized main address and the synchronized repair address according to the synchronized repair signal.

9. An address decoding circuit comprising:
a main address processing block configured to delay a main address, and output a delayed main address as a second main address;
a repair block configured to determine whether the main address corresponds to a failed region, and output a repair address according to a determination result;
a synchronization block configured to synchronize the second main address and the repair address with a synchronization signal, and output a synchronized second main address and a synchronized repair address; and
a decoder configured to decode any one of the synchronized second main address and the synchronized repair address.

10. The address decoding circuit according to claim 9, wherein the repair block compares the main address with an address of the failed region.

11. The address decoding circuit according to claim 9, wherein the repair block outputs a repair signal at a first predetermined level, when the main address is the same as the address of the failed region.

12. The address decoding circuit according to claim 11, wherein the synchronization block synchronizes the repair signal with the synchronization signal, and outputs a synchronized repair signal.

13. The address decoding circuit according to claim 12, wherein the decoder decodes the synchronized second main address when the synchronized repair signal is at a second predetermined level, and decodes the synchronized repair address when the synchronized repair signal is at the first predetermined level.

14. A semiconductor apparatus comprising:
a memory region including a main region and a redundancy region; and
an address decoding circuit configured to process a main address corresponding to the main region,
the address decoding circuit comprising:
a main address processing block configured to latch the main address, and output a latched main address;
a repair block configured to output a repair address and a repair signal, by referring to the main address and information on a failed region;
a synchronization block configured to synchronize the latched main address, the repair address and the repair signal with a synchronization signal, and output a synchronized main address, a synchronized repair address and a synchronized repair signal; and
a decoder configured to decode any one of the synchronized main address and the synchronized repair address in response to a decoding signal.

15. The semiconductor apparatus according to claim 14, wherein the main address processing block latches the main address while the repair block outputs the repair address.

16. The semiconductor apparatus according to claim 14, wherein the main address processing block comprises:
a transfer section configured to receive the main address, and output the main address in response to a latch signal;
a latch section configured to latch the main address transferred from the transfer section; and
an output section configured to output the main address latched by the latch section.

17. The semiconductor apparatus according to claim 14, wherein the repair block outputs the repair signal at a first predetermined level, when the main address is the same as an address of the failed region.

18. The semiconductor apparatus according to claim 17, wherein the decoder decodes any one of the synchronized main address and the synchronized repair address according to whether the synchronized repair signal is at the first predetermined level.

19. The semiconductor apparatus according to claim 14, wherein the information on a failed region is stored in the memory region, and is loaded on the repair block when starting an operation.
